(19) United States
(12) Patent Application Publication
(10) Pub. No.: US 2025/0157838 A1
(43) Pub. Date: May 15, 2025

(54) WAFER TREATMENT DEVICE AND WAFER TREATMENT METHOD

(71) Applicant: SwaySure Technology Co., Ltd., Shenzhen (CN)

(72) Inventor: Zhibo Liu, Shenzhen (CN)

(21) Appl. No.: 18/801,948

(22) Filed: Aug. 13, 2024

(30) Foreign Application Priority Data
Nov. 9, 2023 (CN) 202311490878.3
Nov. 9, 2023 (CN) 202323036015.7

(51) Int. Cl. H01L 21/673; H01L 21/02; H01L 21/306; H01L 21/67

(52) U.S. Cl. CPC H01L 21/67346; H01L 21/67057; H01L 21/67086; H01L 21/02041; H01L 21/30604

(57) ABSTRACT

A wafer treatment device includes a treatment tank, configured for storing a wafer treatment liquid; a support group including a plurality of support portions capable of independently or jointly supporting a wafer to be in an upright state, each support portion has a contact surface to be in contact with the wafer when supporting the wafer; an action system, separately connected to the plurality of the support portions, for driving the plurality of the support portions to move in conjunction with each other; the contact surface of at least one support portion is a state of contacting the wafer when driven by the action system; and the contact surface of the at least one support portion is in a state of being separated from the wafer in a region of intersecting with a liquid surface during being driven by the action system into the wafer treatment liquid.

### CROSS-REFERENCE TO RELATED APPLICATIONS

This application claims priority to Chinese Patent Application 202311490878.3, filed Nov. 9, 2023, and a Chinese Patent Application 202323036015.7, filed Nov. 9, 2023, the entire disclosures of which are incorporated herein by reference.

### TECHNICAL FIELD

The present application belongs to the field of semiconductor technology, and particularly to a wafer treatment device and a wafer treatment method.

### BACKGROUND

In the semiconductor manufacturing process, in order to improve the chip yield and a recovery rate of the wafer, wet cleaning and wet etching technology are particularly important, but when the support structure is used to support the wafer into the treatment tank for wet cleaning or wet etching, air bubbles are easily generated at a position where the wafer is in contact with the support structure, resulting in insufficiently cleaning or etching, and ultimately defects are generated.

### SUMMARY

There are provided a wafer treatment device and a wafer treatment method according to embodiments of the present application. The technical solution is as below:

According to a first aspect of embodiments of the present application, there is provided a wafer treatment device, which includes:
a treatment tank, configured for storing a wafer treatment liquid;
a support group, comprising a plurality of support portions capable of independently or jointly supporting a wafer to be in an upright state, wherein each support portion has a contact surface to be in contact with the wafer when supporting the wafer;
an action system, separately connected to the plurality of the support portions, for driving the plurality of the support portions to move in conjunction with each other;
wherein the contact surface of at least one support portion is a state of contacting the wafer when driven by the action system; and
the contact surface of the at least one support portion is in a state of being separated from the wafer in a region of intersecting with a liquid surface during being driven by the action system into the wafer treatment liquid.

According to a second aspect of embodiments of the present application, there is provided a semiconductor structure, which includes:
adding a wafer treatment liquid to a treatment tank, and supporting a wafer in an upright state using a support group, wherein the support group includes a plurality of support portions respectively connected to an action system, the plurality of support portions are capable of supporting the wafer independently or jointly, and each support portion has a contact surface for contacting the wafer when supporting the wafer;
using the action system to drive the plurality of the support portions to move in conjunction with each other, to drive the wafer into the wafer treatment liquid, wherein during the wafer entering into the wafer treatment liquid:
a contact surface of at least one support portion is in a state of contacting the wafer when driven by the action system; and
the contact surface of at least one support portion is in a state of being separated from the wafer in a region of intersecting with the liquid surface during being driven by the action system into the wafer treatment liquid.

### BRIEF DESCRIPTION OF THE DRAWINGS

The accompanying drawings herein are incorporated into and form a portion of the specification, illustrate embodiments consistent with the present application, and are used in conjunction with the specification to explain the principles of the present application. Obviously, the accompanying drawings in the following description are only some of the embodiments of the present application, and other accompanying drawings may be obtained from these drawings by those skilled in the art without creative labour.

FIG. 1 is a view of a positional relationship of a wafer treatment device with a wafer and a wafer treatment liquid in an embodiment of the present application.

FIG. 2 is a structural view of the first support portion or the second support portion in an embodiment of the present application.

FIG. 3 is a structural view of the first support portion or the second support portion in another embodiment of the present application.

FIG. 4 is a view of the positional relationships of the wafer treatment device with the wafer and the wafer treatment liquid in another embodiment of the present application.

FIG. 5 is a view of the positional relationships of the wafer treatment device with the wafer and the wafer treatment liquid in yet another embodiment of the present application.

FIGS. 6 to 13 are views of the positional relationships of the wafer treatment device with the wafer and the wafer treatment liquid when different stages in the wafer treatment method are finished in embodiments of the present application.

### DETAILED DESCRIPTION OF THE EMBODIMENTS

Embodiments will now be described more fully with reference to the accompanying drawings. However, the embodiments can be implemented in a variety of forms and should not be construed as limitation to the examples set forth herein; rather, the provision of these embodiments allows the present application to be more comprehensive and complete and conveys the idea of the embodiments in a comprehensive manner to those skilled in the art.

In addition, the described features, structures, or characteristics may be combined in one or more embodiments in any suitable manner. In the following description, many specific details are provided thereby giving a full understanding of the embodiments of the present application. However, those skilled in the art will realize that it is possible to practice the technical embodiments of the present application without one or more of the specific details, or that other methods, components, devices, steps, etc. may be employed. In other cases, the well-known methods, devices, implementations, or operations are not shown or described in detail to avoid blurring aspects of the present application.

The present application is described in further detail below in conjunction with the accompanying drawings and specific embodiments. It should be noted herein that the technical features involved in the various embodiments of the present application described below may be combined with each other, as long as they do not constitute a conflict with each other. The embodiments described below by reference to the accompanying drawings are exemplary and are intended to be used to explain the present application and are not to be construed as a limitation of the present application.

In a semiconductor manufacturing process, it is often necessary to use a support structure to support the wafer into a treatment tank to perform a wet cleaning or wet etching process, but because the wafer surface and the surface of the support structure are made of different materials, for example, the wafer surface may include hydrophilic materials such as silicon, silicon oxide, silicon nitride, etc., and in order to prevent the support structure from corrosion by chemicals (hydrofluoric acid, ammonium fluoride, etc.), the surface of the support structure is often made of hydrophobic materials such as a polytetrafluoroethylene (PTFE), but at a moment when the wafer enters into the wafer treatment liquid in the treatment tank, small bubbles are generated easily at a position where the wafer is in contact with the support structure, small bubbles lead to that particles produced by breakage of crystal edge or by-products H₂SiF₆, Si(OH)₄ generated by the chemical reaction, etc. are easily adsorbed on the wafer surface, thereby easily triggering the surface defects. In addition, small bubbles are adsorbed on the wafer surface, there will also be a situation that the wafer at the position where the wafer is in contact with the support structure is not easy to be sufficiently cleaned or wet-etched, thereby affecting the subsequent product manufacturing yield.

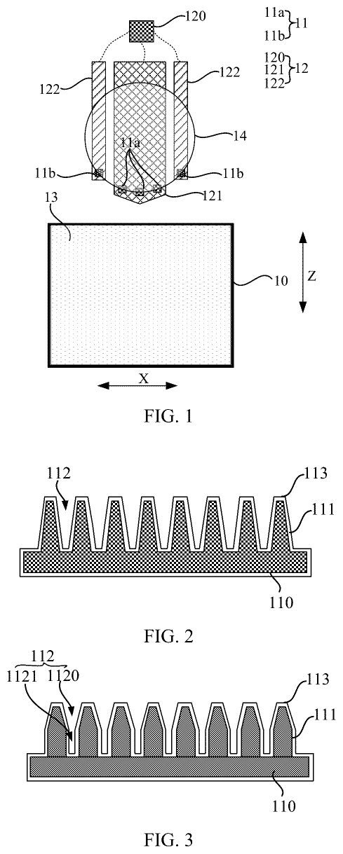

Based on the aforementioned problems, embodiments of the present application provide a wafer treatment device, as shown in FIG. 1, the wafer treatment device includes at least a treatment tank 10, a support group 11, and an action system 12.

The treatment tank 10 is configured to store a wafer treatment liquid 13, and the wafer treatment liquid 13 may be deionised water or a chemical liquid, to process the wafer 14 such as cleaning or etching. For example, the chemical solution may include Diluted HF (DHF), Buffered HF (BHF), Mixture of Sulphuric Acid H₂SO₄, Hydrogen Peroxide H₂O₂ and Deionised Water (SPM), Mixture of Ammonia NH₄OH, Hydrogen Peroxide H₂O₂ and Deionised Water (SC1), Hydrochloric Acid HCl, mixture of hydrogen peroxide H₂O₂ and deionised water (SC2), phosphoric acid H₃PO₄, etc.

The support group 11 may include a plurality of support portions, the plurality of support portions is capable of independently or jointly supporting the wafer 14 in an upright state. Each support portion has a contact surface for contacting the wafer 14 when supporting the wafer 14. The upright state refers to a state that an axial direction of the wafer 14 is perpendicular or approximately perpendicular to the vertical direction Z, and it can be understood that the upright state refers to a state that the axial direction of the wafer 14 is parallel or approximately parallel to the horizontal direction X.

The action system 12 may be separately connected to a plurality of support portions for driving the plurality of support portions to move in conjunction with each other, to drive the wafer 14 to move relative to the wafer treatment liquid 13.

The contact surface of at least one of the support portions can be in a state of contacting with the wafer 14 when driven by the action system 12. The contact surface of at least one of the support portions can be in a state of being separated from the wafer in a region of intersecting with the liquid surface during being driven by the action system into the wafer treatment liquid. That is, the use of the action system 12 and the support group 11 (i.e., the plurality of support portions) in conjunction with each other can enable the wafer 14 to be supported by the support portions in an upright state in the whole process, and also enable the contact surface of at least one of the support portions to be in a state of being separated from the wafer 14 in the region of intersecting with the liquid surface during being driven by the action system 12 into the wafer treatment liquid 13, so as to enable the wafer 14 to be separated from the support portion to enter into the wafer treatment liquid 13 in a contact-free manner, thereby improving the situation that defects are easily generated at the position where the wafer 14 is in contact with the support portion and the wafer 14 at this position is not easy to be sufficiently cleaned or wet-etched.

It should be understood that the entire process mentioned above may include a process in which the wafer 14 enters into the wafer treatment liquid 13, a process in which the wafer 14 is processed in the wafer treatment liquid 13, a process in which the wafer 14 comes out of the wafer treatment liquid 13 after treatment, etc. The following takes a plurality of support portions in the support group of the present application including a first support portion 11a and a second support portion 11b as an example for a specific description.

In this embodiment, a horizontal height of the second support portion 11b is higher than a horizontal height of the first support portion 11a when the first support portion 11a and the second support portion 11b jointly support the wafer 14. In other words, when the first support portion 11a and the second support portion 11b jointly support the wafer 14, a portion of the wafer 14 in contact with the first support portion 11a is closer to a center of the wafer 14 in the vertical direction Z than a portion of the wafer 14 in contact with the second support portion 11b.

It should be noted that the horizontal height in the present application refers to a distance from an object (e.g., a support portion) to a horizontal ground in the vertical direction Z. In addition, a portion of the wafer 14 for contacting a contact surface of the first support portion 11a may be defined as a first contact portion, and a portion of the wafer 14 for contacting a contact surface of the second support portion 11b may be defined as a second contact portion.

The action system 12 may be connected to the first support portion 11a and the second support portion 11b, respectively, and can drive the first support portion 11a and the second support portion 11b to move independently, so as to independently drive the wafer 14 up and down, to enter and exit the wafer treatment liquid 13. In other words, the up and down positions and up and down speeds of the first support portion 11a and the second support portion 11b may be independent to each other, and may be controlled by the action system 12 separately.

The contact surface of the first support portion 11a can be in a state of being separated from the wafer 14 in a region of intersecting with the liquid surface during being driven by the action system 12 into the wafer treatment liquid 13, and the contact surface of the second support portion 11b can be in a state of contacting the wafer when driven by the action system 12, to support the wafer 14 to be in the upright sate when the contact surface of the first support portion 11a is separated from the first contact portion of the wafer 14. The contact surface of the second support portion 11b is in a state of being separated from the second contact portion of the wafer 14 in a region of intersecting with the liquid surface during being driven by the action system 12 into the wafer treatment liquid 13, and the contact surface of the first support portion 11a can be in a state of contacting the wafer when driven by the action system, to support the wafer 14 to be in the upright sate when the contact surface of the second support portion 11b is separated from the second contact portion of the wafer 14.

It should be noted that the contact surface of the support portion may be moved to a position of being separated from the contact portion of the wafer 14 when the action system 12 drives the support portion to descend in the vertical direction Y, or to be a position of being separated from the contact portion of the wafer 14 when the action system 12 drives the support portion to move in the horizontal direction X, etc., which is not limited to the two forms mentioned above, as long as it is possible to ensure that the contact surface of the support portion can be in a state of being separated from the wafer 14 in the region of intersecting with the liquid surface during being driven by the action system into the wafer treatment liquid 13, and will not be described herein.

It is understood that the support portion generally has a certain rigidity and is not susceptible to deformation, and in order to form a stable support, the contact surface of the support portion can be in a state of being separated from the wafer 14 in the region of intersecting with the liquid surface during being driven by the action system into the wafer treatment liquid 13, or the separated support portion as a whole can be separated from the wafer 14. When the support group includes a plurality of support portions that are connected as a single unit, even if the plurality of contact surfaces of the support portions form a continuous surface, which should be understood as that different support portions have different contact surfaces, respectively.

In this embodiment, since the horizontal height of the second support portion 11b is higher than the horizontal height of the first support portion 11a when the first support portion 11a and the second support portion 11b jointly support the wafer 14, i.e., the first contact portion of the wafer 14 is lower than the second contact portion of the wafer 14, thus the action system 12 can be used to drive the first support portion 11a and the second support portion 11b to move correspondingly, such that the first contact portion and the second contact portion of the wafer 14 enter into the wafer treatment liquid 13 successively in a contact-free manner, thereby improving the situation that defects are easily generated on the wafer surface due to bubbles formed by that the material of the wafer 14 is different from that of the support portion, and improving the situation that the wafer at the position where the wafer 14 is in contact with the support portion is not sufficiently cleaned or wet etched. That is, the situation that defects are easily generated at the position where the wafer 14 is in contact with the support portion and the wafer 14 at this position cannot easily be sufficiently cleaned or wet etched can be improved.

In addition, after the wafer 14 is fully located in the wafer treatment liquid 13, a wafer treatment stage can be performed, the first support portion 11a and the second support portion 11b sequentially support the wafer 14 in the wafer treatment stage, so that the first contact portion and the second contact portion of the wafer 14 can alternately and sufficiently contact the wafer treatment liquid 13 in the contact-free manner, and then the situation that the wafer at a position where the wafer 14 is in contact with the support portion cannot be sufficiently cleaned or wet etched due to the narrow space at this position can be further improved, that is, the situation that the wafer at the position where the wafer 14 is in contact with the support portion cannot be sufficiently cleaned or wet etched due to the narrow space at this position, i.e., the situation that the wafer at the position where the wafer 14 is in contact with the support portion is not easy to be sufficiently cleaned or wet etched can be improved. In one embodiment, a sufficient contact cycle with the wafer treatment liquid 13 can be formed by repeating the alternative support action.

The contact-free manner means that the contact portion of the wafer 14 is in a state of being separated from the contact surface of its' corresponding support portion when entering into the wafer treatment liquid 13. Specifically, the action system 12 may first be used to drive at least one of the first support portion 11a and the second support portion 11b to move in the vertical direction Z, so that the contact surface of the first support portion 11a is separated from the first contact portion of the wafer 14, and at this time, the first contact portion of the wafer 14 is in a contact-free state, but the contact surface of the second support portion 11b is in contact with the second contact portion of the wafer 14, so that the action system 12 can be subsequently used to drive the second support portion 11b to descend in the vertical direction Z, to drive the first contact portion of the wafer 14 into the wafer treatment liquid 13 in the contact-free manner. Afterwards, the action system 12 can be used to drive at least one of the first support portion 11a and the second support portion 11b to move in the vertical direction Z, to make the second support portion 11b be separated from the second contact portion of the wafer 14, at this time, the second contact portion of the wafer 14 is in a contact-free state, but the first support portion 11a is in contact with the first contact portion of the wafer 14, so that the action system 12 can be subsequently used to drive the first support portion 11a to descend, so as to drive the second contact portion of the wafer 14 into the wafer treatment liquid 13 in the contact-free state.

It is to be noted that when the action system 12 is used to drive the second support portion 11b to descend to drive the first contact portion of the wafer 14 into the wafer treatment liquid 13 in the contact-free state. The first support portion 11a may also descend or remain motionless when driven by the action system 12, as long as it can be ensured that the first contact portion of the wafer 14 enters into the wafer treatment liquid 13 in a contact-free state. Similarly, when the action system 12 is used to drive the first support portion 11a to descend, to drive the second contact portion of the wafer 14 into the wafer treatment liquid 13 in a contact-free state, the second support portion 11b may also descend or remain motionless when driven by the action system 12, as long as it can be ensured that the second contact portion of the wafer 14 enters into the wafer treatment liquid 13 in a contact-free state.

In this embodiment, the wafer 14 is supported by the first support portion 11a and the second support portion 11b, and the first support portion 11a and the second support portion 11b are driven by the action system 12 to move independently, such that one of the first support portion 11a and the second support portion 11b can be used to support the wafer 14, and the other can be separated from the wafer 14, so that the wafer 14 is separated from the support portion to enter into the wafer treatment liquid 13 in the treatment tank 10 in a contact-free manner, thereby improving the situation that defects are easily generated at the position where the wafer 14 is in contact with the support portion and that the wafer at this position is not easy to be sufficiently cleaned or wet etched.

Exemplarily, there maybe a plurality of the second support portions 11b, which are provided on two opposite sides of the first support portion 11a to cooperate jointly to stably support the wafer 14 when the contact surface of the first support portion 11a is separated from the first contact portion of the wafer 14.

As shown in FIG. 1, two second support portions 11b may be provided and located at the same horizontal height to ensure that the support force on both sides of the wafer 14 is more balanced, so that the support stability of the wafer 14 may be ensured.

One first support portion 11a may be provided, and when one first support portion 11a is provided, in order to ensure that the first support portion 11a can independently and stably support the wafer 14 when the second support portion 11b is separated from the wafer 14, the first support portion 11a can made to be in surface-contact with the wafer 14, and the center of the wafer 14 may be projected in the middle region of the first support portion 11a, i.e. the lowest point of the wafer 14 may be supported in the middle region of the first support portion 11a, but is not limited thereto, a plurality of first support portions 11a can also be provided, e.g., three first support portions as shown in FIG. 1, and the plurality of first support portions 11a are spaced apart along the circumferential direction of the wafer 14, which may support the wafer 14 at many points. The plurality of first support portions 11a are used to cooperate together to stably support the wafer 14.

It should be understood that the number of first support portions 11a is not limited to the three shown in FIG. 1, but may also be one, two, four, etc.

In this embodiment, the support portion may include a support rod 110 and a plurality of restraining walls 111. The plurality of restraining walls 111 may be formed at the top of the support rod 110 and spaced apart in an extension direction of the support rod 110. A restraining groove 112 is formed between two adjacent restraining walls 111 and the support rod 110, and the restraining groove 112 is used for insertion of the wafer 14 to constrain the wafer 14 from moving in its axial direction. The joint action of the support rod 110 and the restraining walls 111 further ensures the stability of the support portion supporting the wafer 14.

Exemplarily, three or more restraining walls 111 are provided in the support portion, so that two or more restraining grooves 112 may be formed, so that a plurality of wafer 14 may be supported to enter into the treatment tank 10 for batch treatment simultaneously, that is, the wafer treatment device of the present embodiment may be a wafer batch treatment device to improve production capacity and reduce production costs.

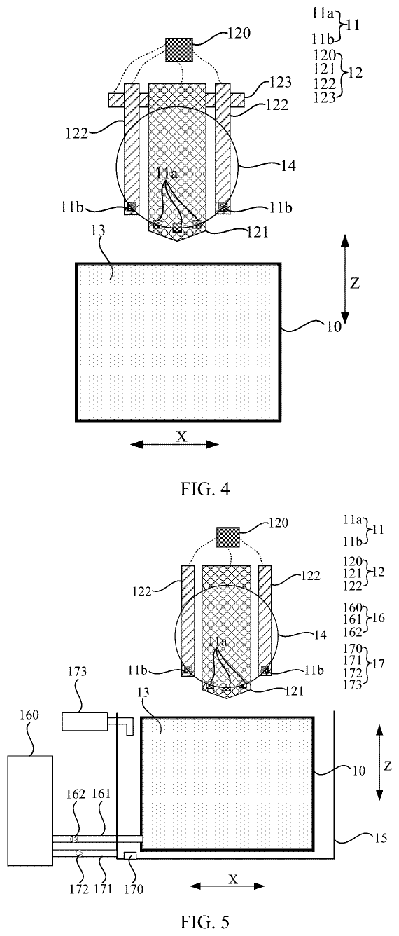

In an optional embodiment, as shown in FIG. 2, in a direction from the top to the bottom of the restraining groove 112: the groove width of the restraining groove 112 gradually decreases in the extension direction of the support rod 110 (which may also be understood to be the axial direction of the wafer 14), in other words, the restraining groove 112 may be a V-type restraining groove, which, while providing axial constraints on the wafer 14, also facilitates the smooth insertion of the wafer 14, and reduces the contact area between the restraining wall 111 and the wafer 14, then the wear rate of the wafer 14 can be reduced.

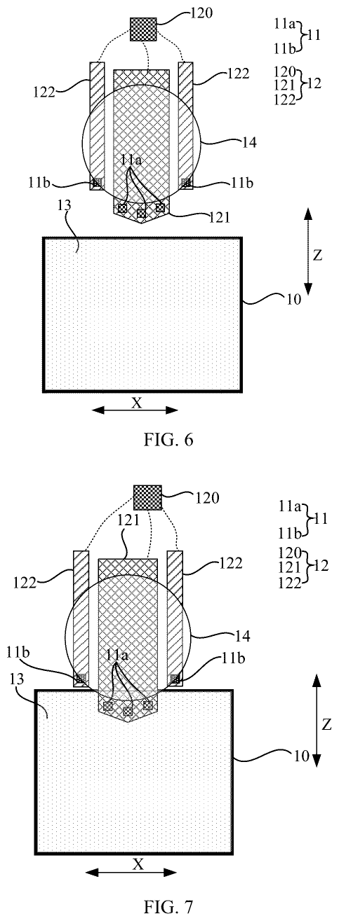

In another optional embodiment, as shown in FIG. 3, the restraining groove 112 may include a guiding groove segment 1120 and a limiting groove segment 1121 communicated with each other. The guiding groove segment 1120 is located on a side of the limiting groove segment 1121 away from the support rod 110. From the top to the bottom of the restraining groove 112: the groove width of the guiding groove segment 1120 is gradually reduced in the extension direction of the support rod 110. From the top to the bottom of the restraining groove 112: the groove width of the limiting groove segment 1121 is equal in the extension direction of the support rod 110, the guiding groove segment 1120 is mainly used to facilitate the smooth insertion of the wafer 14, and the limiting groove segment 1121 mainly plays a role of axially restraining the wafer 14, so as to better ensure that the wafer 14 is in the vertical support state.

Further, the height of the limiting groove segment 1121 may be less than or equal to 3 mm, for example: 1 mm, 2 mm, 3 mm, etc., so as to play a role of axially restraining the wafer 14 while also reducing the contact area between the restraining wall 111 and the wafer 14, and then the wear rate of the wafer 14 can be reduced.

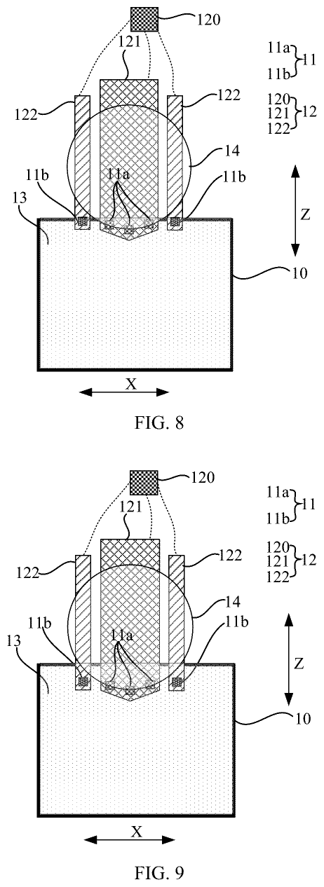

In this embodiment, as shown in FIGS. 3 and 4, the support portion, in addition to including the support rod 110 as mentioned above, may also include a cushion layer 113 wrapping the restraining wall 111, and the hardness of the cushion layer 113 is less than the hardness of the restraining wall 111, so that the wear rate of the wafer 14 may be reduced when the wafer 14 is inserted into the restraining groove 112, while ensuring the support capacity of the support portion.

It is to be noted that the cushion layer 113 is not limited to wrapping the restraining wall 111, but may also wrap the support rod 110, so as to also reduce the breakage of the wafer 14 when colliding and contacting the support rod 110.

For example, the restraining wall 111 and the support rod 110 of the present embodiment may be an integrated structure to ensure structural stability of the support portion. The materials of the support rod 110 and the restraining wall 111 include, but are not limited to, quartz, and the material of the cushion layer 113 includes, but is not limited to, polytetrafluoroethylene, to provide cushioning capacity while also protecting the support rod 110 and the restraining wall 111, to prevent the support rod 110 and the restraining wall 111 from corrosion by the wafer treatment liquid 13.

It should be appreciated that in order to ensure the support performance of the support portions, all the support portions in the support group 11 are located in a region below the center of the wafer 14 (i.e.: located in a region of the center of the wafer 14 near the bottom of the treatment tank 10).

In addition, it should also be noted that the plurality of support portions in the support group 11 is not limited to the first support portion 11a and the second support portion 11b as mentioned above, and the structure and number of the first support portion 11a and the second support portion 11b are not limited to contents as mentioned above, and the first support portion 11a and the second support portion 11b in this embodiment can be designed as a clamping claw structure that can be opened and closed, so that when one support portion is separated from the support wafer 14, the other support portion may clamp the wafer 14 to ensure its support stability.

In this embodiment, the action system 12 may include a driving mechanism 120, a first lifting mechanism 121, and a second lifting mechanism 122. The first lifting mechanism 121 may be connected to the driving mechanism 120 and the first support portion 11a, and the first lifting mechanism 121 is configured to drive the first support portion 11a to move in the vertical direction Z when driven by the driving mechanism 120. The second lifting mechanism 122 may be connected to the driving mechanism 120 and each second support portion 11b, and the second lifting mechanism 122 is configured to drive all the second support portions 11b to move synchronously in the vertical direction Z when driven by the driving mechanism 120. That is to say, each of the first support portion 11a and the second support portion 11b is matched with the lifting mechanism to drive it to move in the vertical direction Z, so as to reduce the difficulty of the driving mechanism 120 driving the first support portion 11a and the second support portion 11b, respectively. In addition, the same group of support portions may be connected to the same lifting mechanism, i.e., a plurality of the second support portions 11b are connected to the same second lifting mechanism 122, in order to further simplify the driving design of the driving mechanism 120.

It should be noted that the driving mechanism 120 of this embodiment may be a drive controller such as a microcontroller, which will not be overly described herein, as long as it can drive the first lifting mechanism 121 and the second lifting mechanism 122 to carry out corresponding operations (i.e., the wafer treatment method mentioned in the later embodiments). The first lifting mechanism 121 and the second lifting mechanism 122 may include a screw lifting mechanism, a gear and rack lifting mechanism, etc., and will not be specifically limited herein, as long as it can drive the support portion to complete movement in the vertical direction Z when driven by the driving mechanism 120.

As shown in FIG. 4, the action system 12 may also include a horizontal moving mechanism 123, which may be connected to the driving mechanism 120, the first lifting mechanism 121, and the second lifting mechanism 122. The horizontal moving mechanism 123 may drive the first lifting mechanism 121, the first support portion 11a, the second lifting mechanism 122, and the second support portion 11b to move horizontally in the horizontal direction X, such design allows the horizontal moving mechanism 123 to horizontally move the processed wafer 14 as a whole away from above the treatment tank 10, so as to avoid delaying the subsequent operation process, and the unprocessed wafer 14 can also be carried on the support group at other positions first, and then moved to above the treatment tank 10 by the horizontal moving mechanism 123, so as to improve the production treatment efficiency.

Similarly, the present embodiment fails to limit the horizontal moving mechanism 123 too much, as long as it can achieve the function of driving the first lifting mechanism 121, the first support portion 11a, the second lifting mechanism 122, and the second support portion 11b to move horizontally as a whole.

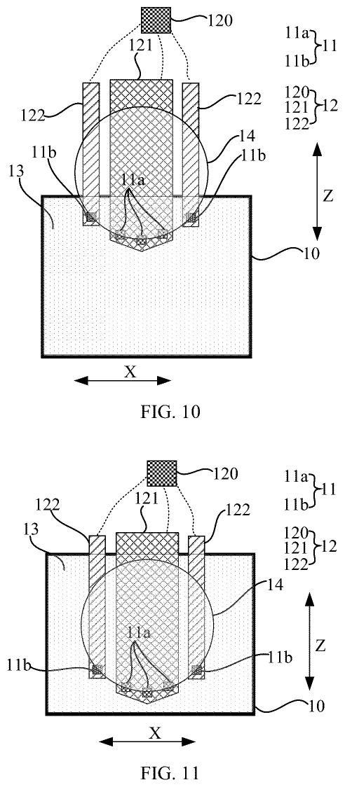

As shown in FIG. 5, the wafer treatment device of the embodiment of the present application also includes an overflow recovery tank 15 and a liquid supply system 16. The overflow recovery tank 15 is provided with the treatment tank 10 inside, and an inner groove wall of the overflow recovery tank 15 is spaced apart from an outer groove wall of the treatment tank 10, for recovering the wafer treatment liquid overflowed from the treatment groove 10. The liquid system 16 can include a liquid storage tank 160, a liquid supply pipeline 161, the liquid supply pump 162 connected to the liquid supply pipeline 161. One end of the liquid supply pipeline 161 is connected to the treatment tank 10, and the other end is connected to the liquid supply storage tank 160, the liquid supply storage tank 160 is configured for storing the wafer treatment liquid 13, and the liquid supply pump 162 is configured for pumping the wafer treatment liquid 13 in the liquid supply storage tank 160 to the treatment tank 10 via the liquid supply pipeline 161.

In this embodiment, the liquid supply system 16 is provided to provide the wafer treatment liquid 13 to the treatment tank 10, the wafer treatment liquid 13 in the treatment tank 10 can be kept in an overflow state during wafer treatment, so that the wafer treatment liquid in the treatment tank 10 can be in the state of flowing and constantly renewed, so that the composition and concentration can be kept stable to improve the effect of cleaning or wet etching the wafer 14. In addition, the overflowed wafer treatment liquid 13 is recovered by the overflow recovery tank 15 to avoid polluting operation environment.

It should be understood that the liquid supply system 16 not only allows the wafer treatment liquid in the treatment tank 10 to be in an overflow state during wafer treatment, but also to be in an overflow state during the wafer 14 entering into the wafer treatment liquid.

As shown in FIG. 5, the wafer treatment device may also include a liquid return system 17, and the liquid return system 17 may include a concentration detector 170, a liquid return pipeline 171, and a liquid return pump 172. The concentration detector 170 may be provided in the overflow recovery tank 15 for detecting the concentration information of the wafer treatment liquid 13 in the overflow recovery tank 15; one end of the liquid return pipeline 171 is connected to the overflow recovery tank 15, and the other end is connected to the liquid supply storage tank 160. The liquid return pump 172 is connected to the liquid return pipeline 171 and the concentration detector 170, and the liquid return pump 172 is configured to pump the wafer treatment liquid 13 recovered in the overflow recovery tank 15 to the liquid supply storage tank 160 via the liquid return pipeline 171 when the concentration information detected by the concentration detector 170 meets a target concentration range, so as to achieve the recovery of the wafer treatment liquid 13, thereby reducing costs while also avoiding the situation that the recovered wafer treatment liquid 13 fails to meet the standard due to the concentration of the wafer treatment liquid 13 not meeting the standard, thereby ensuring that the wafer treatment liquid 13 sent from the liquid supply storage tank 160 to the treatment tank 10 always meets the requirements, and to improve the treatment effect of the wafer 14.

Further, as shown in FIG. 5, the liquid return system 17 also includes a replenisher 173 connected to the concentration detector 170, the replenisher 173 is configured to add corresponding materials to the overflow recovery tank 15 when the concentration information detected by the concentration detector 170 fails to fall in the target concentration range, and to stop adding corresponding materials to the overflow recovery tank 15 when the concentration information detected by the concentration detector 170 falls in the target concentration range, so that the recovery utilization rate of the wafer treatment liquid 13 can be improved, so that the wafer treatment liquid 13 is in a state of recovery in the entire wafer treatment device.

It should be understood that the wafer treatment liquid 13 in the treatment tank 10 in the embodiments of the present application can also be in a non-overflow state during the whole process, as long as it is possible to achieve efficient cleaning or etching of the wafer. The design of structures such as the liquid return pipeline 171 and the liquid return pump 172 in the overflow recovery tank 15 and the liquid return system 17 may also be omitted if they are in a non-overflow state, which is determined based on the specific situation.

Based on the wafer treatment device mentioned in any of the foregoing embodiments, embodiments of the present application also provide a wafer treatment method, and the wafer treatment method may include at least a step S1, a step S2, and a step S3, each of which is described in detail below.

Step S1, adding the wafer treatment liquid 13 to the treatment tank 10.

For example, after determining that the treatment tank 10 is placed in the aforementioned overflow recovery tank 15, the wafer treatment liquid 13 is added to the treatment tank 10 by the aforementioned liquid supply system, so that the wafer treatment liquid 13 in the treatment tank 10 is in an overflow state at least during the treatment stage of the wafer 14, so as to make the wafer treatment liquid 13 in the treatment tank 10 liquid, which improves the cleaning or etching effect of the wafer 14.

It should be understood that the wafer treatment liquid 13 in the treatment tank 10 is not limited to being in an overflow state at the treatment stage of the wafer 14, but may also be in an overflow state at the liquid inlet stage, at the liquid outlet stage, etc. of the wafer 14, which is determined as actual.

In step S2, the wafer 14 is supported in an upright state by using the aforementioned support group 11. For example, before starting the stage of entering the wafer treatment liquid 13 (i.e.: the liquid inlet stage of the wafer 14), all of the support portions in the support group 11 may be used to jointly support the wafer 14 to be in an upright position above the wafer treatment liquid 13, or some of the support portions in the support group 11 may be used to support the wafer 14 in an upright position above the wafer treatment liquid 13.

In step S3, using the action system 12 mentioned above to drive the plurality of the support portions to move in conjunction with each other, to drive the wafer 14 into the wafer treatment liquid 13, during the wafer 14 entering into the wafer treatment liquid 13: the contact surface of the at least one support portion is in a state of contacting the wafer 14 when driven by the action system 12; the contact surface of the at least one support portion in a state of being separated from the wafer 14 in a region of intersecting with the liquid surface during being driven by the action system into the wafer treatment liquid.

At least two support portions are configured to be at different horizontal heights when jointly supporting the wafer 14, and the contact surface of each of the support portions is separated from the wafer 14 in the region of intersecting with the liquid surface during being driven by the action system 12 into the wafer treatment liquid 13.

The wafer treatment method is described in detail by taking the plurality of support portions in the support group 11 including the first support portion 11a and the second support portion 11b mentioned above as an example.

The process of the wafer 14 entering into the wafer treatment liquid 13 in this embodiment may include: after determining that a contact surface of the first support portion 11a is separated from the wafer 14, sequentially performing a first descending stage, a first adjustment stage and a second descending stage.

In the first descending stage: using the action system 12 to drive the second support portion 11b to descend in a vertical direction Z, to drive a first contact portion of the wafer 14 into the wafer treatment liquid 13 in a state of being separated from the contact surface of the first support portion 11a, and a second contact portion of the wafer 14 is located above the wafer treatment liquid 13, as shown in FIG. 7.

In the first adjustment stage: using the action system 12 to drive at least one of the first support portion 11a and the second support portion 11b to move in the vertical direction Z, to drive the contact surface of the second support portion 11b to be in a position of being separated from the second contact portion of the wafer 14, and to drive the contact surface of the first support portion 11a to be in a position of contacting the first contact portion of the wafer 14, to support the second contact portion of the wafer 14 to be above the wafer treatment liquid 13, as shown in FIG. 8.

In the second descending stage: using the action system 12 to drive the first support portion 11a to descend in the vertical direction Z, to drive the second contact portion of the wafer 14 into the wafer treatment liquid 13 in a state of being separated from the contact surface of the second support portion 11b, as shown in FIG. 9.

In this embodiment, the first support portion 11a and the second support portion 11b are driven by the action system 12 to move separately, so that the first contact portion and the second contact portion of the wafer 14 enter into the wafer treatment liquid 13 successively in the contact-free manner, thereby improving the situation that defects are easily generated on the wafer surface due to small bubbles generated by that the material of the wafer 14 is different from that of the support portion, and improving the situation that the wafer at the position where the wafer 14 is in contact with the support portion cannot be sufficiently cleaned or wet etched.

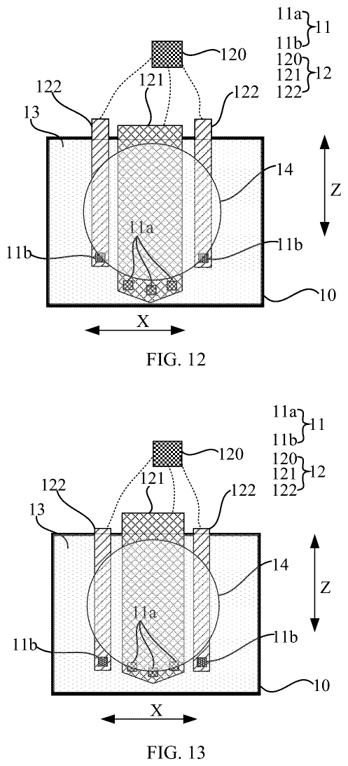

Optionally, before entering the first descending stage, if the contact surface of the first support portion 11a is in contact with the first contact portion of the wafer 14, the process of the wafer 14 entering into the wafer treatment liquid 13 further includes: an initial adjustment stage. In the initial adjustment stage: using the action system 12 to drive at least one of the first support portion 11a and the second support portion 11b to move in the vertical direction Z, to make the contact surface of the first support portion 11a to be in a position of being separated from the first contact portion of the wafer 14, and the second support portion 11b to support the wafer 14 to be above the wafer treatment liquid 13, as shown in FIG. 6.

Exemplarily, in the initial adjustment stage: the step of using the action system 12 to drive at least one of the first support portion 11a and the second support portion 11b to move in the vertical direction Z may specifically include: using the action system 12 to drive the contact surface of the first support portion 11a to descend in the vertical direction Z to be in a position of being separated from the first contact portion of the wafer 14 and keep the second support portion 11b immobile in an original position of the second support portion 11b, to make the second support portion 11b to support the wafer 14 to be above the wafer treatment liquid 13. Such design can simplify the design of the actuation of the action system 12 in the initial adjustment stage, and can shorten the descending journey of the wafer 14 entering into the wafer treatment liquid 13 subsequently, but is not limited thereto, in the initial adjustment stage: using the action system 12 to drive the first support portion 11a and the second support portion 11b to descend simultaneously in the vertical direction Z, a descending speed of the first support portion 11a is greater than a descending speed of the second support portion 11b, so that the contact surface of the first support portion 11a is descended to a position of being separated from the first contact portion of the wafer 14, and the second support portion 11b supports the wafer 14 to be above the wafer treatment liquid 13.

Optionally, in this embodiment, a specific position where the contact surface of the first support portion 11a descends in the vertical direction Z to be separated from the first contact portion of the wafer 14 is a position where a topmost point (e.g., the topmost point of the restraining wall 111 away from the support rod 110) of the first support portion 11a is lower a distance of 1 mm to 2 mm than its' corresponding crystal edge (the edge of the wafer), which not only enables the first contact portion of the wafer 14 to enter into the wafer treatment liquid 13 in a contact-free manner subsequently, but also facilitates rapid contact of the first support portion 11a with the first contact portion of the wafer 14 in the subsequent first adjustment stage, to support the wafer 14.

Exemplarily, in the first descending stage: while the action system 12 is used to drive the second support portion 11b to descend in the vertical direction Z, the action system 12 may also be used to drive the first support portion 11a to descend in the vertical direction Z. In this way, the risk of the first support portion 11a interfering with descending of the wafer 14 during the descending process of the wafer 14 driven by the second support portion 11b may be reduced, such that it can be ensured that the contact surface of the first support portion 11a always remains in a state of no contact with the first contact portion of the wafer 14 during the first contact portion of the wafer 14 entering into the wafer treatment liquid 13.

Further, in the first descending stage: the action system 12 is used to drive the first support portion 11a and the second support portion 11b to descend simultaneously and at equal speeds, so as to not only ensure that the first contact portion of the wafer 14 enters into the wafer treatment liquid 13 in a state of being separated from the contact surface of the first support portion 11a, but also reduce the difficulty of driving the action system 12.

Exemplarily, in the first adjustment stage: the step of using the action system 12 to drive at least one of the first support portion 11a and the second support portion 11b to move in the vertical direction Z includes: using the action system 12 to drive the first support portion 11a to descend at a first speed while driving the second support portion 11b to descend at a second speed greater than the first speed, to make the contact surface of the second support portion 11b move to a position of being separated from the second contact portion of the wafer 14 and the contact surface of the first support portion 11a move to a position of contacting with the first contact portion of the wafer 14.

In this embodiment, the first support portion 11a and the second support portion 11b are driven to descend at different speeds, so that the action of separating the contact surface of the second support portion 11b from the second contact portion of the wafer 14, and the action of the contact surface of the first support portion 11a contacting the first contact portion of the wafer 14 are performed simultaneously, the efficiency of the work can be improved.

Optionally, in this embodiment, a specific position where the contact surface of the second support portion 11b descends to be separated from the second contact portion of the wafer 14 is a position where the topmost point of the second support portion 11b (e.g., the topmost point of the restraining wall 111 away from the support rod 110) is lower a distance of 1 mm to 2 mm than its' corresponding crystal edge (an edge of the wafer), which not only enables the second contact portion of the wafer 14 to enter into the wafer treatment liquid 13 in a contact-free manner subsequently, but also facilitates rapid contact of the second support portion 11b with the second contact portion of the wafer 14 in the subsequent second adjustment stage, to support the wafer 14.

Exemplarily, in the second descending stage: while the action system 12 is used to drive the first support portion 11a to descend in the vertical direction Z, the action system 12 may also be used to drive the second support portion 11b to descend in the vertical direction Z. In this way, the risk of the second support portion 11b interfering with descending of the wafer 14 during the descending process of the wafer 14 driven by the first support portion 11a may be reduced, such that it can be ensured that the contact surface of the second support portion 11b always remains in a state of no contact with the second contact portion of the wafer 14 during the second contact portion of the wafer 14 entering into the wafer treatment liquid 13.

Further, in the second descending stage: the action system 12 is used to drive the first support portion 11a and the second support portion 11b to descend simultaneously and at equal speeds, which not only ensures that the second contact portion of the wafer 14 enters into the wafer treatment liquid 13 in a state of being separated from the contact surface of the second support portion 11b, but also reduces the difficulty of driving the action system 12.

In an embodiment of the present application, the aforementioned process of the wafer 14 entering into the wafer treatment liquid 13 may further include: a second adjustment stage and a third descending stage performed sequentially after the second descending stage. In the second adjustment stage: using the action system 12 to drive at least one of the first support portion 11a and the second support portion 11b to move in the vertical direction Z, to make the contact surface of the first support portion 11a be in a position of contacting the first contact portion of the wafer 14, and the contact surface of the second support portion 11b be in a position of contacting the second contact portion of the wafer 14, as shown in FIG. 10. In the third descending stage: using the action system 12 to drive the first support portion 11a and the second support portion 11b to descend simultaneously and at equal speeds, to make the wafer 14 supported on the first support portion 11a and the second support portion 11b fully enter into the wafer treatment liquid 13, as shown in FIG. 11.

In this embodiment, the contact surfaces of both the first support portion 11a and the second support portion 11b are first made to contact with the wafer 14 in the second adjustment stage to support the wafer 14 simultaneously, so that the wafer 14 can be kept stably supported on the first support portion 11a and the second support portion 11b in the third descending stage to reduce the risk of wobble of the wafer during the descending process of the wafer.

It will be appreciated that both the second adjustment stage and the third descending stage are optional. In some embodiments, it is also possible to use only a portion of the support portions in the support group to carry the wafer 14 to descend.

Optionally, in the second adjustment stage: the step of using the action system 12 to drive at least one of the first support portion 11a and the second support portion 11b in the vertical direction Z may specifically include: using the action system 12 to drive the first support portion 11a to descend at a third speed while driving the second support portion 11b to descend at a fourth speed less than the third speed, to make the contact surface of the second support portion 11b move to a position of contacting the second contact portion of the wafer 14 and the contact surface of the first support portion 11a keep in a position of contacting the first contact portion of the wafer 14.

In this embodiment, the first support portion 11a and the second support portion 11b are driven to descend at different speeds, so that the action of the second support portion 11b contacting the second contact portion of the wafer 14, and the action of the first support portion 11a driving the wafer 14 to descend are performed simultaneously, the efficiency of the wafer 14 entering into the wafer treatment liquid 13 can be improved.

By way of example, the first speed, the second speed, the third speed, and the fourth speed mentioned above may be in a range of 10 mm/sec to 350 mm/sec, for example: the first speed, the second speed, the third speed, and the fourth speed may be 10 mm/sec, 50 mm/sec, 100 mm/sec, 150 mm/sec, 200 mm/sec, 250 mm/sec, 300 mm/sec, 350 mm/sec, etc., in order to improve the entry speed of the wafer 14 while avoiding a situation that the descent speed is too fast, resulting in unstably supporting the wafer 14.

In a specific embodiment of the present application, after the wafer 14 fully enters into the wafer treatment liquid 13, the wafer treatment method may also include: performing a treatment stage. The treatment stage may include a first treatment stage and a second treatment stage performed sequentially.

In a first treatment stage: using the action system 12 to drive at least one of the first support portion 11a and the second support portion 11b to move in the vertical direction Z, to make one of the first support portion 11a and the second support portion 11b alone support the wafer 14 to be fully within the wafer treatment liquid 13, and the contact surface of the other be in a position of being separated from the wafer 14; in a second treatment stage: using the action system 12 to drive at least one of the first support portion 11a and the second support portion 11b to move in the vertical direction Z, to make the other support the wafer 14 to be fully within the wafer treatment liquid 13 and the contact surface of the one of the first support portion 11a and the second support portion 11b be in a position of being separated from the wafer 14. In an optional embodiment, the first treatment stage is shown in FIG. 12 and the second treatment stage is shown in FIG. 13. It will be appreciated that in another embodiment, the first treatment stage is as shown in FIG. 13 and the second treatment stage is as shown in FIG. 12.

In this embodiment, the first treatment stage and the second treatment stage are used to make the first support portion 11a and the second support portion 11b sequentially support the wafer 14 in the wafer treatment stage, such that the first contact portion and the second contact portion of the wafer 14 can alternately fully contact the wafer treatment liquid 13 in a contact-free manner, and then the situation that the wafer at a position where the wafer 14 is in contact with the support portion cannot be sufficiently cleaned or wet etched due to the narrow space at this position can be further improved, that is, the situation that the wafer at the position where the wafer 14 is in contact with the support portion cannot be sufficiently cleaned or wet etched due to the narrow space at this position, i.e., the situation that the wafer at the position where the wafer 14 is in contact with the support portion is not easy to be sufficiently cleaned or wet etched can be improved. In one embodiment, a sufficient contact cycle with the wafer treatment liquid 13 can be formed by repeating the alternative support action.

In this embodiment, the position of separation may be that a position where the topmost point of the support portion (e.g., the topmost point of the restraining wall 111 away from the support rod 110) is lower a distance of 1 mm to 2 mm than its' corresponding crystal edge (the edge of the wafer), which not only enables the contact portion of the wafer 14 to fully contact the wafer treatment liquid 13 in a contact-free manner, but also achieves a rapid alternation of the first treatment stage and the second treatment stage.

Optionally, in the second treatment stage: the step of using the action system 12 to drive at least one of the first support portion 11a and the second support portion 11b in the vertical direction includes: using the action system 12 to drive the contact surface of the other to rise in the vertical direction to a position of contacting the wafer 14; and using the action system 12 to drive the contact surface of the one of the first support portion 11a and the second support portion 11b to descend in the vertical direction Z to a position of being separated from the wafer 14, to increase the efficiency of the first contact portion and the second contact portion of the wafer 14 being alternately and sufficiently treated by the wafer treatment liquid 13.

Further, in the second treatment stage: the action system 12 is first used to drive the second one to rise to be in contact with the wafer 14, and then the action system 12 is used to drive the first one to descend to a position of being separated from the wafer 14, so that it can ensured that the wafer 14 is supported stably while realizing the alternate treatment.

By way of example, both the first treatment stage and the second treatment stage mentioned above are preformed a plurality of times and alternately.

It is to be noted that a positional relationship between the support portion, the wafer treatment liquid, and the wafer may be detected by a sensor in each stage in the wafer treatment method in the present application, and when the positional relationship meets the requirements of the corresponding stage, then an action system is used to drive the support portion to perform a coordinated action, but is not limited thereto, and the stages may be realized in turn by setting up a set of fixed procedures.

In this embodiment, the terms “first”, “second”, “third”, “fourth”, etc. are used only for descriptive purposes, and are not to be understood as indicating or implying relative importance or implicitly specifying the number of technical features indicated. Accordingly, the features defined as “first”, “second”, “third”, “fourth” may expressly or implicitly include one or more technical features. In the description of the present application, “more than one” means two or more, unless otherwise expressly limited.

In the description of the present specification, the terms “some embodiments”, “exemplarily”, etc. means that the specific features, structures, materials, or characteristics described in conjunction with the embodiments or examples are included in at least one embodiment or example of the present application. In this specification, schematic expressions of the above terms do not necessarily refer to the same embodiment or example. Moreover, the specific features, structures, materials, or characteristics described may be combined in a suitable manner in any one or more of the embodiments or examples. Furthermore, without contradicting each other, those skilled in the art may combine and combine different embodiments or examples and features of different embodiments or examples described in this specification.

Although the embodiments of the present application have been shown and described above, it is understood that the above embodiments are exemplary and should not be construed as a limitation of the present application, and that those skilled in the art may make changes, modifications, substitutions and variations to the above embodiments within the scope of the present application, and therefore any changes or modifications made in accordance with the claims and specification of the present application shall fall within the scope of the application.

What is claimed is:

1. A wafer treatment device, comprising:
a treatment tank, configured for storing a wafer treatment liquid;
a support group, comprising a plurality of support portions capable of independently or jointly supporting a wafer to be in an upright state, wherein each support portion has a contact surface to be in contact with the wafer when supporting the wafer;
an action system, separately connected to the plurality of support portions, for driving the plurality of support portions to move in conjunction with each other;
wherein the contact surface of at least one support portion is a state of contacting the wafer when driven by the action system; and
the contact surface of the at least one support portion is in a state of being separated from the wafer in a region of intersecting with a liquid surface during being driven by the action system into the wafer treatment liquid.

2. The wafer treatment device according to claim 1, wherein the plurality of support portions comprise a first support portion and second support portions provided on two opposite sides of the first support portion, wherein a horizontal height of each second support portion is higher than a horizontal height of the first support portion when the first support portion and the second support portions jointly support the wafer; wherein:
a contact surface of the first support portion is in a state of being separated from the wafer in a region of intersecting with the liquid surface during being driven by the action system into the wafer treatment liquid, and a contact surface of each second support portion is in a state of contacting the wafer when driven by the action system; and
the contact surface of each second support portion is in a state of being separated from the wafer in a region of intersecting with the liquid surface during being driven by the action system into the wafer treatment liquid, and the contact surface of the first support portion is in a state of contacting the wafer when driven by the action system.

3. The wafer treatment device according to claim 2, wherein the action system comprises:
a driving mechanism;
a first lifting mechanism, connected to the driving mechanism and the first support portion, wherein the first lifting mechanism is configured to drive the first support portion to move in a vertical direction when driven by the driving mechanism; and
a second lifting mechanism, connected to the driving mechanism and all the second support portions, wherein the second lifting mechanism is configured to drive all the second support portions to move synchronously in the vertical direction when driven by the driving mechanism.

4. The wafer treatment device according to claim 3, further comprising:
a horizontal moving mechanism, connected to the driving mechanism, the first lifting mechanism and the second lifting mechanism, wherein the horizontal moving mechanism is configured to drive the first lifting mechanism, the first support portion, the second lifting mechanism and the second support portions to move horizontally in a horizontal direction when driven by the driving mechanism.

5. The wafer treatment device according to claim 1, wherein each support portion comprises:
a support rod; and
a plurality of restraining walls, formed on a top of the support rod and spaced apart in an extension direction of the support rod;
wherein a restraining groove is formed between two adjacent restraining walls and the support rod for insertion of the wafer.

6. The wafer treatment device according to claim 1, further comprising:
an overflow recovery tank, provided with the treatment tank inside, wherein an inner tank wall of the overflow recovery tank is spaced apart from an outer tank wall of the treatment tank for recovering the wafer treatment liquid overflowed from the treatment tank; and
a liquid supply system, comprising a liquid supply storage tank, a liquid supply pipeline and a liquid supply pump connected to the liquid supply pipeline, wherein one end of the liquid supply pipeline is connected to the treatment tank and another end of the liquid supply pipeline is connected to the liquid supply storage tank, and the liquid supply storage tank is configured to store the wafer treatment liquid, and the liquid supply pump is configured to pump the wafer treatment liquid from the liquid supply storage tank to the treatment tank via the liquid supply pipeline.

7. The wafer treatment device according to claim 6, further comprising a liquid return system, wherein the liquid return system comprises:
a concentration detector, provided in the overflow recovery tank for detecting concentration information of the wafer treatment liquid in the overflow recovery tank;
a liquid return pipeline, with one end connected to the overflow recovery tank and another end connected to the liquid supply storage tank; and
a liquid return pump, connected to the liquid return pipeline and the concentration detector, wherein the liquid return pump is configured to pump the wafer treatment liquid recovered in the overflow recovery tank via the liquid return pipeline to the liquid supply storage tank when the concentration information detected by the concentration detector falls in a target concentration range.

8. The wafer treatment device according to claim 7, wherein the liquid return system further comprises:
a replenisher, connected to the concentration detector, wherein the replenisher is configured to add corresponding material to the overflow recovery tank when the concentration information detected by the concentration detector fails to fall in the target concentration range, and to stop adding the corresponding material to the overflow recovery tank when the concentration information detected by the concentration detector falls in the target concentration range.

9. A wafer treatment method, comprising:
adding a wafer treatment liquid to a treatment tank, and supporting a wafer in an upright state using a support group, wherein the support group comprises a plurality of support portions respectively connected to an action system, the plurality of support portions are capable of supporting the wafer independently or jointly, and each support portion has a contact surface for contacting the wafer when supporting the wafer;
using the action system to drive the plurality of support portions to move in conjunction with each other, to drive the wafer into the wafer treatment liquid, wherein during the wafer entering into the wafer treatment liquid:
a contact surface of at least one support portion is in a state of contacting the wafer when driven by the action system; and
a contact surface of at least one support portion is in a state of being separated from the wafer in a region of intersecting with a liquid surface during being driven by the action system into the wafer treatment liquid.

10. The wafer treatment method according to claim 9, wherein at least two support portions are configured to be at different horizontal heights when jointly supporting the wafer, and the contact surface of each support portion is in a state of being separated from the wafer in the region of intersecting with the liquid surface during being driven by the action system into the wafer treatment liquid.

11. The wafer treatment method according to claim 10, wherein the plurality of support portions comprise a first support portion and second support portions provided on two opposite sides of the first support portion, and a horizontal height of each second support portion is higher than a horizontal height of the first support portion when the first support portion and the second support portions jointly support the wafer, wherein during the wafer entering into the wafer treatment liquid comprises:
after determining that a contact surface of the first support portion is in a position of being separated from the wafer, sequentially performing a first descending stage, a first adjustment stage and a second descending stage, wherein:
in the first descending stage, using the action system to drive the second support portions to descend in a vertical direction, to drive a first contact portion of the wafer into the wafer treatment liquid in a state of being separated from the contact surface of the first support portion, and a second contact portion of the wafer is located above the wafer treatment liquid, and the first contact portion is a portion of the wafer for contacting the contact surface of the first support portion, and the second contact portion is a portion of the wafer for contacting a contact surface of each second support portion;
in the first adjustment stage, using the action system to drive at least one of the first support portion and the second support portions to move in the vertical direction, to drive the contact surface of each second support portion to a position of being separated from the second contact portion of the wafer, and to drive the contact surface of the first support portion to a position of contacting the first contact portion of the wafer, to support the second contact portion of the wafer to be above the wafer treatment liquid; and
in the second descending stage, using the action system to drive the first support portion to descend in the vertical direction, to drive the second contact portion of the wafer into the wafer treatment liquid in a state of being separated from the contact surface of each second support portion.

12. The wafer treatment method according to claim 11, wherein before entering the first descending stage, when the contact surface of the first support portion is in a position of contacting the first contact portion of the wafer, a process of the wafer entering into the wafer treatment liquid further comprises: an initial adjustment stage,
in the initial adjustment stage, using the action system to drive at least one of the first support portion and the second support portions to move in the vertical direction, to make the contact surface of the first support portion be in a position of being separated from the first contact portion of the wafer, and the second support portions to support the wafer to be above the wafer treatment liquid.

13. The wafer treatment method according to claim 12, wherein using the action system to drive at least one of the first support portion and the second support portions to move in the vertical direction in the initial adjustment stage comprises:
using the action system to drive the contact surface of the first support portion to descend in the vertical direction to a position of being separated from the first contact portion of the wafer, and keep the second support portions immobile in an original position of the second support portions, to make the second support portions to support the wafer to be above the wafer treatment liquid; or
using the action system to drive the first support portion and the second support portions to descend simultaneously in the vertical direction, wherein a descending speed of the first support portion is greater than a descending speed of the second support portions, so that the contact surface of the first support portion is descended to a position f being separated from the first contact portion of the wafer, and each second support portion supports the wafer to be above the wafer treatment liquid.

14. The wafer treatment method according to claim 11, wherein:
in the first descending stage and/or in the second descending stage, while using the action system to drive the second support portions to descend in the vertical direction, using the action system to drive the first support portion to descend in the vertical direction.

15. The wafer treatment method according to claim 11, wherein using the action system to drive at least one of the first support portion and the second support portions to move in the first adjustment stage comprises:
using the action system to drive the first support portion to descend at a first speed while driving the second support portions to descend at a second speed greater than the first speed, to make the contact surface of the second support portions move to a position of being separated from the second contact portion of the wafer and the contact surface of the first support portion move to a position of contacting with the first contact portion of the wafer.

16. The wafer treatment method according to claim 11, wherein during the wafer entering into the wafer treatment liquid further comprises a second adjustment stage and a third descending stage performed sequentially after the second descending stage, wherein:
in the second adjustment stage, using the action system to drive at least one of the first support portion and the second support portions to move in the vertical direction, to make the contact surface of the first support portion be in a position of contacting with the first contact portion of the wafer, and make the contact surface of the second support portions be in a position of contacting the second contact portion of the wafer; and
in the third descending stage, using the action system to drive the first support portion and the second support portions to descend simultaneously and at equal speeds, to make the wafer supported on the first support portion and the second support portions fully enter into the wafer treatment liquid.

17. The wafer treatment method according to claim 16, wherein using the action system to drive at least one of the first support portion and the second support portions to move in the vertical direction in the second adjustment stage comprises:
using the action system to drive the first support portion to descend at a third speed while driving the second support portions to descend at a fourth speed less than the third speed, to make the contact surface of the second support portions move to a position of contacting the second contact portion of the wafer and the contact surface of the first support portion keep in a position of contacting the first contact portion of the wafer.

18. The wafer treatment method according to claim 11, wherein after the wafer fully enters into the wafer treatment liquid, the wafer treatment method further comprises:
performing a treatment stage, wherein the treatment stage comprises a first treatment stage and a second treatment stage in sequence, wherein:
in the first treatment stage: using the action system to drive at least one of the first support portion and the second support portions to move in the vertical direction, to make one of the first support portion and the second support portions alone support the wafer to be fully within the wafer treatment liquid, and make the contact surface of the other be in a position of being separated from the wafer; and
in a second treatment stage: using the action system to drive at least one of the first support portion and the second support portions to move in the vertical direction, to make the other support the wafer to be fully within the wafer treatment liquid, and make the contact surface of the one of the first support portion and the second support portions be in a position of being separated from the wafer.

19. The wafer treatment method according to claim 18, wherein:
the first treatment stage and the second treatment stage are performed a plurality of times; and
using the action system to drive at least one of the first support portion and the second support portions to move in the vertical direction in the second treatment stage comprises:
using the action system to drive the contact surface of the other to rise in the vertical direction to a position of contacting with the wafer; and
using the action system to drive the contact surface of the one of the first support portion and the second support portions to descend in the vertical direction to a position of being separated from the wafer.

20. The wafer treatment method according to claim 19, wherein adding the wafer treatment liquid to the treatment tank comprises:
after determining that the treatment tank is placed in an overflow recovery tank, using a liquid supply system to add the wafer treatment liquid to the treatment tank, to make the wafer treatment liquid in the treatment tank be in a state of overflow at least during the treatment stage of the wafer.
